(19) United States
(12) Patent Application Publication
(10) Pub. No.: US 2020/0335454 A1
(43) Pub. Date: Oct. 22, 2020

(54) RADIATION-RESISTANT METAL OXIDE SEMICONDUCTOR COMPOSITION CONTAINING ZINC-INDIUM-TIN OXIDE, AND PREPARATION METHOD AND USE THEREOF

(71) Applicant: Sogang University Research & Business Development Foundation, Seoul (KR)

(72) Inventors: Choongik Kim, Seoul (KR); Myung Gil Kim, Seoul (KR); Dongil Ho, Seoul (KR); Byung Kyu Park, Seoul (KR)

(73) Assignee: Chung Ang University Industry Academic Cooperation Foundation, Seoul (KR)

(21) Appl. No.: 16/849,256

(22) Filed: Apr. 15, 2020

(30) Foreign Application Priority Data
Apr. 16, 2019 (KR) 10-2019-0044445

(51) Int. Cl. H01L 23/552; H01L 21/84; H01L 21/02

(52) U.S. Cl. CPC H01L 23/552; H01L 21/02175; H01L 21/84

(57) ABSTRACT

The present invention relates to a radiation-resistant metal oxide semiconductor composition containing zinc-indium-tin oxide (ZITO) exhibiting radiation resistance, and a preparation method and use thereof. In the present invention, the radiation-resistant metal oxide semiconductor composition containing ZITO exhibiting radiation resistance is used in an electronic device for radiation exposure, which is used in outer space, nuclear power plants, or in spaces where medical or security devices are utilized by means of radiation, and thus, the damage caused by radiation can be prevented, thereby improving the electrical properties of the device (e.g., turn-on voltage (Vₒₙ)), and the life-span and reliability thereof.

### TECHNICAL FIELD

The present invention relates to a radiation-resistant metal oxide semiconductor composition containing zinc-indium-tin oxide (ZITO) exhibiting radiation resistance, and a preparation method and use thereof.

### BACKGROUND ART

Space, nuclear, medical, and security industries, etc. are highly valuable from the industrial and economic perspectives and are expected to grow in importance in the future. Outer space, nuclear power plants, medical devices, or security devices that utilize radiation, etc. are exposed to a large amount of radiation such as protons, gamma rays, X-rays, etc. In particular, under such an environment, electronic devices mounted on electronic equipment suffer from various problems such as performance degradation, malfunction, etc. due to exposure to radiation over time. These problems lead to economic waste by shortening the lifespan of electronic equipment, and additionally, operation errors of these electronic equipment are the cause of increasing the production cost as multiple complementary devices may be necessary.

Currently, it is known that Si-based electronic devices, which are used in all electronic devices, cannot be stably operated in a radiation environment, due to problems such as performance degradation or shortening of lifespan, etc. Therefore, studies on materials that can replace Si-based electronic devices and on damages caused by radiation have been conducted in various fields. In particular, the effects of protons, which are the main components of cosmic radiation, have been studied more extensively. Accordingly, there is a growing need for various materials which are resistant to radiation in antenna arrays, sensor arrays, X-ray image sensors, reactor monitoring, etc. used in the field of aerospace applications. However, studies on changes in performance of some semiconductor materials by irradiation have been reported, but studies on materials having high radiation resistance have rarely been reported. Additionally, it has not been reported by what mechanism radiation specifically influences various semiconductor materials.

Electronic devices used in the medical, security, and nuclear energy fields where radiation exposure is inevitable, including the space industry which is the next-generation high-tech industry, must be stably operated under radiation with minimal performance degradation or shortening of lifespan. Electronic circuits are essential for computing and/or controlling electronic devices in outer space (such as satellites, space stations, etc.), nuclear power plants, spaces where medical devices for diagnosis and treatment and security devices are exposed to radiation, or in high altitude environments. In particular, electronic devices used in aerospace require a superior level of operational reliability.

Thin film transistors (TFTs) are used as display driving-transistors in various portable electronic devices such as mobile phones, laptops, and PDAs because of their small area and space-saving property.

The field effect transistor (FET) is a transistor that controls the current of a source and a drain by applying a voltage to a gate electrode to generate a gate through which electrons or holes flow due to an electric field of a channel. In the metal oxide semiconductor field effect transistor (MOSFET), a gate portion is composed of a metal electrode on an oxide film of a semiconductor, and the MOSFET is a device that is becoming the mainstream of current integrated circuits.

Thin film transistors (TFTs), in which an oxide semiconductor material is used for the channel layer, have an advantage that they can be formed at a low temperature. Additionally, thin film transistors have an advantage in that any type of insulating film can be used as a substrate because a thin-film type semiconductor film is used as a channel through which electrons or holes pass compared to MOSFET, which uses bulk crystalline silicone (Si) as a semiconductor. Because of the advantage, not only glass but also plastic substrates and even paper can be used as a substrate of TFTs, and various deposition methods can be used to fabricate the same, and also, there is no limitation on the expandability of the substrate. Accordingly, it is possible not only to use a flexible substrate, but also to provide stretchable electronics.

The largest reference point in the TFT structure depends on where the gate electrode is located around the semiconductor film, and it is largely classified into a bottom gate if the gate electrode is located under the semiconductor, and a top gate if the gate electrode is formed on the semiconductor. Additionally, it is classified as a coplanar type if the gate electrode is located planar to the semiconductor according to the position of channel formation and the arrangement of SD, and as a staggered type if the gate electrode and the semiconductor are located at spatially different places.

In the metal oxide semiconductor field effect transistors (MOSFETs), various effects of radiation damage on electronic devices have been studied, since the effects of radiation damage on insulators or semiconductor-insulator interfaces have been found.

To date, the mechanisms for the effects of radiation damage on the insulators or the semiconductor-insulator interfaces have been found to some extent for Si-based transistors. In contrast, damage to the semiconductor itself has been reported several times, but the detailed mechanism has not been elucidated. Additionally, much research has been conducted on the effects of radiation on organic materials and oxides as a substitute material for Si, and it has been found that materials such as organic compounds formed based on covalent bonds experience severe bond angle distortion or bond breakage upon irradiation with high energy radiation and thus exhibit significant performance degradation when applied to electronic devices. Meanwhile, it has been known that materials formed based on ionic bonds such as oxides are somewhat stable against high energy radiation.

For example, it has been found in research that when 70 keV proton was irradiated to zinc oxide (ZnO) nanowires for a wide range of irradiation doses, the defects' density was increased with an increasing proton irradiation dose (NaNO, 2011, 6(3), 259-263), and a research was conducted to investigate the effect of irradiation on the performance degradation of indium zinc oxide-based thin-film transistors (IZO-TFTs), after which the performance was recovered (Surf Coat. Tech. 2010, 205, S109-S114). Additionally, the effect of radiation on indium-zinc-oxide (IZO) oxide semiconductors has been investigated up to a total dose of 1 Mrad, and it was found that the performance of the device increased to some extent, but the cause has not been analyzed (Thin Solid Films 2013, 539, 342-344).

Meanwhile, the research team from Jiaotong University in China has investigated the effect of radiation on HfO₂ insulator and it was found that the performance was decreased with increased radiation dose (IEEE Trans. Dielectr. Electr. Insul. 2014, 21, 1792-1800). Seoul National University has investigated the effect of 10 MeV proton irradiation on molybdenum disulfide (MoS₂), and it was found that the charge trap in the semiconductor and the semiconductor-insulator interface increased with increased irradiation dose (ACS Nano. 2014, 8(3), 2774-2781). According to the IEEE International Conference, the degree of performance change was confirmed by irradiating various irradiation doses to a-IGZO thin film transistors, and the degree of recovery was also observed (RTEICT IEEE International Conference, IEEE, 2016, 1816-1819). Additionally, according to BPEX, there was nearly no effect on C-axis-aligned crystalline In—Ga—Zn—O (CAAC-IGZO) thin-film transistors (TFTs) after irradiation with 12C⁶⁺ and the prospects for the use of CAAC-IGZO TFTs in heavy-ion radiotherapy was suggested (Biomed Phys. Eng. Express 3, 2017. 045009). The present inventors fabricated thin-film transistors (TFTs) by selecting various metal oxides such as ZnO, IGZO or ZTO, and the change in performance of the TFTs was investigated upon 5 MeV proton irradiation with radiation doses of 10¹³, 10¹⁴, and 10¹⁵ cm⁻², and it was found that ZTO-based oxide thin-film transistors exhibited radiation resistance (Adv Funct. Mater. 2018, 28, 1802717).

### DISCLOSURE

### Technical Problem

In the present invention, Sn-based metal oxide semiconductor materials were selected and irradiated with various ionizing radiation (proton rays, gamma rays, X-rays), and as a result, zinc-indium-tin-oxide (ZITO) semiconductor materials having stable electrical properties were developed. Accordingly, the present invention has been implemented based on these findings.

### Technical Solution

The first aspect of the present invention provides a radiation-resistant metal oxide semiconductor composition containing zinc-indium-tin-oxide (ZITO) exhibiting radiation resistance.

The second aspect of the present invention provides a radiation-durable oxide thin film transistor (TFT) for radiation exposure, wherein a channel layer is formed of the radiation-resistant metal oxide semiconductor composition containing radiation-resistant ZITO of the first aspect in order to reduce performance degradation or malfunction when exposed to radiation.

The third aspect of the present invention provides a radiation-durable electronic device for radiation exposure, wherein a radiation-resistant metal oxide semiconductor layer is formed of the radiation-resistant metal oxide semiconductor composition containing radiation-resistant ZITO of the first aspect in order to reduce performance degradation or malfunction when exposed to radiation

The fourth aspect of the present invention provides a method for preparing the radiation-resistant metal oxide semiconductor composition containing radiation-resistant ZITO of the first aspect, including confirming the formation of oxygen vacancy or the degree thereof in a metal oxide semiconductor material or metal oxide semiconductor layer by irradiating protons to a ZITO-containing metal oxide semiconductor material having a specific composition ratio of Zn:In:Sn or a device fabricated using the same.

The fifth aspect of the present invention provides a method for evaluating the radiation durability of an electronic device fabricated using a ZITO-containing metal oxide semiconductor material, including confirming the formation of oxygen vacancy or the degree thereof in a metal oxide semiconductor layer by irradiating protons to an electronic device fabricated using a ZITO-containing metal oxide semiconductor material.

Hereinafter, the present invention will be described in more detail.

ZnO is an n-type semiconductor applied to various devices. ZnO has the advantages of high field-effect mobility, wide bandgap and low-temperature process suitability. The conductivity of zinc based on oxide semiconductors usually varies with ionized carriers such as Zn interstitial (Zni), oxygen vacancy and oxygen interstitial (Oi). The oxygen vacancy acts as an electronic trap to control the conductivity of the oxide semiconductors, and may increase as the annealing temperature increases as an electron donor.

The present inventors, through previous studies, confirmed the effects of proton irradiation on zinc oxide (Zn)), indium-gallium-zinc oxide (IGZO), and zinc-tin oxide (ZTO), which are typical oxide semiconductor materials, and found that oxides containing Zn and Sn in an appropriate ratio can inhibit the formation of vacancy production caused by proton irradiation.

As such, based on the previous findings that oxides containing Sn element are resistant to proton irradiation, in the present invention, Sn-based oxide semiconductor materials such as GITO, GTO, and GSZO including zinc-indium-tin oxide (ZITO), were fabricated and irradiated with protons. As a result, ZITO showed not only a superior stability compared to ZTO, which was previously found to be resistant to radiation, and but also stable electrical properties against gamma rays and X-rays (FIGS. 2 to 4), and accordingly, the present invention has been implemented based thereon.

Ionizing radiation is largely divided into particle radiation and photon radiation. Ionizing radiation basically ionizes materials, causing damage to the materials. Particle radiation consists of particles such as alpha rays, beta rays, proton rays, and neutron rays. Photon radiation is a type of electromagnetic wave which is classified into gamma rays and X-rays. Proton rays not only produce an effect of ionizing materials with particle radiation, but also exhibit an impurity production effect of producing impurities by injecting hydrogen molecules into the material, and an atom displacement effect by rearranging atoms present inside the materials, in a complex manner. In contrast, photon radiation, such as gamma rays and X-rays, rarely produces the atom displacement effect due to the Compton effect (Table 1). Table 1 summarizes the effects of radiation damage on substances according to different types of radiation.

TABLE 1

| Radiation | Impurity Production | Atom Displacement | Ionization | Energy Release |
|---|---|---|---|---|
| Thermal | Directly by absorption | Yes, indirectly | Indirectly | Indirectly |
| (eV) neutron | reactions (mostly | | | |
| Fast (MeV) | thermal neutrons), also | Multiple displace- | | |
| neutron | may lead to more | ments via scattering | | |
| | radiations | reactions; can cause | | |
| Fission | Become impurities | displacement of | These highly charged | Considerable heat |
| fragment | themselves | “knock-on” atoms | ions cause considerable | deposition over a |
| | | | ionization, and they | very short range |
| | | | emit β and γ | |
| Alpha | He buildup can cause | Yes, may cause atom | Causes sizable | Yes, over a very short |
| | pressurization problems | displacement | ionization | range |
| Proton | H buildup can also | Yes | Directly | Yes, over a short |
| | cause pressurization | | | range |
| Beta | n/a | Some displacement | Directly | Localized heat |
| | | | | deposition |
| Photon (γ | n/a | Rare displacements | Indirectly | Gamma heating over |
| and X ray) | | (via Compton effect) | | large distance |

The atom displacement, which causes permanent damage to materials, redistributes the internal metal ions and oxygen in the metal oxide, creating defects such as oxygen vacancies, which trap charge carriers such as electrons or holes, resulting in reduction of mobility during device operation, thereby reducing performance. Meanwhile, the ionization that causes temporary damage to materials generates electron-hole pairs by absorbing energy in the metal oxides, so that electrons or holes between insulators or insulator interfaces are trapped during device operation, thereby shifting the on voltage or the threshold voltage, resulting in device instability.

Oxygen vacancy formation barrier is formed in the order of In₂O₃<ZnO<SnO₂. That is, oxygen vacancy is less likely to be formed in the order of In₂O₃<ZnO<SnO₂.

Zinc-indium-tin oxide (ZITO), which is a material containing Zn and Sn and in which the electrical properties are enhanced due to the addition of In. In the present invention, it was found that ZITO is a material which enables stable operation of ZITO-based electronic devices even under photon-based radiation such as gamma rays and X-rays as well as particle radiation such as protons (FIGS. 2 to 4). In particular, ZITO shows significant resistance to the formation of defects such as oxygen vacancy as the mobility of ZITO is almost unchanged or slightly decreased even under various radiations, and it seems that the electron-hole pairs are rapidly recombined to inhibit the electrons or holes between insulators or insulator interfaces to be trapped, as there is almost no voltage and threshold voltage shift. Therefore, ZITO can be used as a metal oxide semiconductor material in the medical or security industries, in addition to special environments such as outer space and nuclear power plants.

Additionally, despite that the radiation dose used in the Examples was the amount that the satellites are exposed to protons occupying the most of the outer space in satellite orbits for several decades, and was a considerable amount that the equipment mainly used in medical or security field is exposed to gamma rays and X-rays for hundreds of years. ZITO was significantly stable. Therefore, ZITO, in which the composition of Zn:In:Sn is controlled to exhibit radiation resistance according to the present invention, can be used as a base material for electronic devices for satellites, antennas, sensors, medical equipment, and security equipment used in outer space, nuclear power plants, medical and security fields.

The present invention provides a radiation-resistant metal oxide semiconductor composition containing zinc-indium-tin oxide (ZITO) exhibiting radiation resistance. The degree of resistance exerted by ZITO on proton rays, gamma rays and/or X-rays can be controlled according to the composition of Zn:In:Sn.

Most of metal oxides are semiconductors and are similar to metal catalysts as their conductivity is drastically increased at high temperatures.

Metal oxide semiconductors are compound semiconductors formed by ionic bonds between metal cations and oxygen anions. The main components of the conduction band minimum (CBM) of the oxide semiconductors are mainly the s orbitals of the metals constituting the oxide semiconductors, while the valence band maximum (VBM) is composed mainly of the p orbitals of oxygen. The oxide semiconductors are n-type semiconductors wherein the majority carriers are the electrons with limitation of hole carriers. The primary determinants for the electrical properties of the oxide semiconductors are the oxygen vacancy and hydrogen doped during the process. For example, in the case of InGaZnO, the most representative oxide semiconductor, when it is a semiconductor having a composition rich in In, which has the weakest bond with oxygen among indium (In), gallium (Ga), and zinc (Zn), which are the metals constituting the semiconductor, oxygen vacancies are easily formed, which act as a factor of increasing the carrier concentration in the semiconductor. Additionally, hydrogen in a sputtering machine during a thin film-forming process of oxide semiconductors or hydrogen introduced during the TFT process plays a critical role in increasing the carrier concentration of the semiconductors. The oxide semiconductors show a feature in that the mobility increases along with the carrier concentration until about 10×10²¹ cm⁻³. As a result, proper control of the carrier concentration is very important for securing the properties of the oxide TFT.

Types of metals or nonmetals, which are components constituting the oxide semiconductors used in oxide TFT, are very diverse. In particular, In and Sn are elements that have a great effect on the increase in mobility as the s orbitals are easily overlapped.

The reason as to why the oxide semiconductors exhibit a great mobility even in an amorphous state is that the main component of the conduction band is the s orbital of the metal, which is less dependent on the bond angle. However, when the s orbitals of various metal cations form the conduction band minimum (CBM) in the amorphous state, the degree of overlap with each cation may be different, which may cause fluctuation of the CBM, thereby limiting the movement of electrons. In order to exhibit a high mobility beyond the energy barrier in the CBM, the carrier concentration of the oxide semiconductor should be higher than that of other semiconductors.

Tin in the oxide semiconductor material suppresses the formation of oxygen vacancy during proton irradiation. For example, highly-charged Sn⁴⁺ based a-ZTO exhibited excellent resistance to vacancy formation and structural distortion when subjected to high energy proton irradiation. For dynamic chemical bond stabilization, a-ZTO (4:1) exhibited an optimized local structure with a flexible quasi-stable amorphous structure, thus can facilitate chemical bond recovery and improve radiation resistance of oxide semiconductors.

Additionally, based on the findings of the present invention that ZITO containing tin (Sn) and indium (In) exhibits superior stability against irradiation compared to ZTO containing tin (Sn), it was confirmed that the change in the properties due to irradiation, especially proton irradiation, is inhibited, when the metal oxide semiconductor material contains ZITO, and thus the improved radiation resistance of the ZITO-containing oxide semiconductor material can be applied to radiation-durable semiconductor devices for radiation exposure and various devices using the same.

Since zinc-indium-tin oxide (ZITO) may be used as a semiconductor material for electronic devices such as transistors, the radiation-resistant metal oxide semiconductor composition of the present invention may be one in which a radiation-resistant ZITO forms a metal oxide semiconductor layer of a radiation-resistant electronic device. For example, the radiation-resistant ZITO may form a metal oxide semiconductor layer of a radiation-resistant transistor.

Transistors are semiconductor devices used to amplify or switch electronic signals and electric power using semiconductors. Transistors are one of the most common basic components of electronic devices. The field effect transistor (FET) is a transistor that controls the current of a source and a drain by applying a voltage to a gate electrode to generate a gate through which electrons or holes flow due to an electric field of a channel.

For example, the radiation-resistant metal oxide semiconductor composition containing ZITO exhibiting radiation resistance can be applied as a channel material of a driving transistor, a transistor constituting a peripheral circuit of a memory device, or a channel material of a selection transistor, and can also be applied as an inorganic barrier coating of a plastic substrate for food packaging.

Meanwhile, the oxide semiconductor film for forming the oxide semiconductor layer may be formed through chemical vapor deposition (CVD) or physical vapor deposition (PVD). Therefore, the ZITO-containing metal oxide semiconductor composition according to the present invention may be, for example, a radiation-resistant oxide semiconductor target formed by sintering ZITO.

The radiation-resistant metal oxide semiconductor composition according to the present invention is characterized in that the composition of ZITO is controlled within the range of Zn:In:Sn=4 to 2:1:1 such that ZITO exhibits radiation resistance. For example, the composition of the radiation-resistant ZITO can be controlled in the step of fabricating a precursor before fabricating into a semiconductor for a TFT device.

When zinc (Zn) with a relatively flexible bond due to its tetrahedral structure and tin (Sn), which inhibits oxygen vacancy, are maintained at a proper ratio of 4 to 2:1, it is possible to mitigate structural distortions or minimize the formation of oxygen vacancies, when the energy is applied to the material from the outside. In particular, when indium (In), which increases the electrical properties, is added thereto to some extent, the composition can be used as a metal oxide semiconductor which is stable to external energy such as radiation, while maintaining high electrical performance.

In the case of SiO₂, which is used as an insulator in the field effect transistors upon proton irradiation, if there is no bias, hole trapping does not occur except at the oxide-insulator interface, and electrons and holes generated by proton irradiation recombine. Unlike SiO₂—Si, the oxide semiconductor and insulator interface are stable because the insulator does not lose oxygen to the semiconductor and thus no oxygen vacancies are formed. The change in the properties of the semiconductor devices caused by radiation is attributed to the generation of defects in the metal oxide semiconductor material itself by proton irradiation, that is, the increase in the formation of oxygen vacancy, rather than the trapped charge formed by radiation in the insulator and insulator-semiconductor interface.

Since the change in the properties of the device is attributed to the increase in the formation of oxygen vacancy according to the radiation dose upon proton irradiation to the oxide semiconductor material, it is possible to develop a ZITO-containing metal oxide semiconductor material with radiation resistance, for example, to design the composition ratio of Zn:In:Sn of the radiation-resistant ZITO material, by confirming the degree of increase of the formation of oxygen vacancy according to the radiation dose.

Therefore, the method for preparing a radiation-resistant metal oxide semiconductor composition containing radiation-resistant zinc-indium-tin oxide (ZITO) according to the present invention includes confirming the formation of oxygen vacancy or the degree thereof in a metal oxide semiconductor material or metal oxide semiconductor layer by irradiating protons to a ZITO-containing metal oxide semiconductor material having a specific composition ratio of Zn:In:Sn or a device fabricated using the same.

The method for preparing a radiation-resistant metal oxide semiconductor composition containing radiation-resistant ZITO according to the present invention may further include determining the crystal structure and/or the contents of zinc (Zn), indium (In) and tin (Sn) of the ZITO-containing oxide semiconductor material in order to impart a desired degree of radiation resistance/durability to the ZITO-containing oxide semiconductor material.

In order to impart a desired radiation resistance/durability to the ZITO-containing oxide semiconductor material, the crystal structure and/or the content of zinc (Zn), indium (In) and tin (Sn) of the ZITO-containing oxide semiconductor material may be determined by irradiating protons to the ZITO-containing metal oxide semiconductor material or a device fabricated using the same, and confirming the formation of oxygen vacancy and the degree thereof in the metal oxide semiconductor material.

For example, the composition and/or the crystal structure of ZITO may be selected by preparing two or more ZITO-containing metal oxide semiconductor materials having a specific composition ratio of Zn:In:Sn and comparing the degree of oxygen vacancy formation after each proton irradiation. If the degree of oxygen vacancy formation after a predetermined proton irradiation reaches a desired level, the composition ratio and/or crystal structure of the ZITO may be selected, even without such comparative analysis.

Additionally, the method for evaluating the radiation durability of an electronic device fabricated using a ZITO-containing metal oxide semiconductor material according to the present invention includes confirming the formation of oxygen vacancy or the degree thereof in a metal oxide semiconductor layer by irradiating protons to an electronic device fabricated using a ZITO-containing metal oxide semiconductor material.

In the present specification, the formation of oxygen vacancy and the degree thereof can be confirmed by determining the amount of free electrons generated when oxygen vacancy exists in the metal oxide semiconductor material or metal oxide semiconductor layer to be analyzed.

Accordingly, the formation of oxygen vacancy and the degree thereof can be determined by analyzing ESR peaks obtained from free electrons generated at the oxygen vacancy in the oxide semiconductor material through electron spin resonance (ESR) before and after proton irradiation, or analyzing the O vacancy peaks and/or M-OH peaks through X-ray photoelectron spectroscopy.

Additionally, the method for producing a radiation-resistant metal oxide semiconductor composition containing radiation-resistant ZITO according to the present invention and/or the method for evaluating the radiation durability of an electronic device fabricated using a ZITO-containing metal oxide semiconductor material according to the present invention may further include confirming the degree of turn-on voltage (Vₒₙ) change before and after irradiation of proton rays, gamma rays, and X-rays after fabricating an oxide semiconductor TFT device, in which the ZITO-containing metal oxide semiconductor material to be analyzed is used as a channel layer in order to enhance accuracy.

In general, the turn-on voltage is a voltage that drops when a current flow in the forward direction from the transistor, and has a different value depending on the type of materials that make up the thin film transistor. Additionally, when the turn-on voltage is measured after irradiating protons to the thin film transistor, the turn-on voltage value is shifted to the (−) side due to the generation of additional electrons by the proton irradiation.

As described above, radiation causes changes in the on voltage or threshold voltage and the mobility due to the formation of defects or electron-hole pairs in the material. Thus, as used herein, “radiation resistance” may be a case where the on voltage or threshold voltage and the mobility are minimally changed or are almost not changed. In this regard, it is difficult to express the “radiation resistance” in terms of a numerical range because the allowable values for change and required radiation dose of each field are different for various fields that suffer from degradation caused by radiation. Therefore, it can be considered that radiation resistance is exhibited as long as it is within the range of allowable change in the radiation dose required for each field of use.

For example, in the case of proton rays, when XPS peak is analyzed before and after 5 MeV proton irradiation with radiation dose of 10¹⁴ cm⁻² through XPS analysis, and if the rate of increase of oxygen vacancy generated in the material due to radiation is within 20%, the material is considered to be resistant to protons, and further, as the value decreases, the material becomes more resistant. Additionally, when a TFT device is fabricated from a semiconductor material and the transfer curves before and after proton irradiation are compared, and as a result, if the change in on voltage or threshold voltage is from +10 V to −10 V and the change in mobility is less than 10 times, it can also be considered to be resistant to protons.

For example, in the case of gamma rays, when XPS peak is analyzed before and after 1 MeV gamma ray irradiation with radiation dose of 10 Mrad (100 Kgy) through XPS analysis, and if the rate of increase of oxygen vacancy generated in the material due to radiation is within 20%, the material is considered to be resistant to gamma rays, and further, as the value decreases, the material becomes more resistant. Additionally, when a TFT device is fabricated from a semiconductor material and the transfer curves before and after gamma ray irradiation are compared, and as a result, if the change in on voltage or threshold voltage is from +10 V to −10 V and the change in mobility is less than 10 times, it can also be considered to be resistant to gamma rays.

For example, in the case of X-rays, when XPS peak is analyzed before and after 1 MeV X-ray irradiation with radiation dose of 100 Kgy through XPS analysis, and as a result, if the rate of increase of oxygen vacancy generated in the material due to radiation is within 20%, the material is considered to be resistant to X-rays, and further, as the value decreases, the material becomes more resistant. Additionally, when a TFT device is fabricated from a semiconductor material and the transfer curves before and after X-ray irradiation are compared, and as a result, if the change in on voltage or threshold voltage is from +10 V to −10 V and the change in mobility is less than 10 times, it can also be considered to be resistant to X-rays.

Additionally, the present invention provides a radiation-durable oxide thin film transistor (TFT) for radiation exposure, which is characterized in that a channel layer is formed of the radiation-resistant metal oxide semiconductor composition containing radiation-resistant ZITO of the present invention described above in order to reduce performance degradation or malfunction during exposure to radiation.

Additionally, the present invention provides a radiation-durable electronic device for radiation exposure, which is characterized in that a radiation-resistant metal oxide semiconductor layer is formed of the radiation-resistant metal oxide semiconductor composition containing radiation-resistant ZITO of the present invention described above in order to reduce performance degradation or malfunction during exposure to radiation.

In the present invention, the electronic device for radiation exposure may be an electronic device used in outer space, such as satellite, space station, etc., nuclear power plants, or spaces where medical devices and security devices are utilized by means of radiation. Non-limiting examples of the electronic device is a display (e.g., OLED, LCD), sensor (e.g., image sensor), micro electro mechanical system (MEMS), electronic paper, electronic skin, solar cell, radio frequency identification (RFID) tag, etc.

The radiation-resistant electronic device for radiation exposure according to the present invention may be equipped with a radiation-durable transistor in which a channel layer is formed of the radiation-resistant metal oxide semiconductor composition containing radiation-resistant ZITO of the present invention described above.

The radiation-durable oxide thin film transistor (TFT) for radiation exposure according to the present invention can be used as a radiation-durable electrical signal switch for radiation exposure. Therefore, the radiation-durable electrical device for radiation exposure according to the present invention may use, for example, the radiation-resistant oxide TFT according to the present invention may be used as an electric signal switch.

Additionally, the radiation-durable oxide TFT for radiation exposure according to the present invention may be used as a backplane of OLED, LCD, electronic paper, etc. A display is an apparatus that receives an electrical signal and provides an optical signal that can be recognized by the human eye, and a backplane transmits an electrical signal to a device that generates an optical signal in the display.

A conventional electronic device may be those in which at least one semiconductor device is formed on a substrate. In particular, the semiconductor device may be a thin film transistor, capacitor, diode, light-emitting device, active matrix organic light-emitting diode (AMOLED), organic light-emitting device, active matrix quantum dot light-emitting diode, quantum dot light-emitting diode, display, secondary cell, piezoelectric element, sensor or solar battery, etc. Preferably, the semiconductor device may be an oxide semiconductor thin film transistor, organic light-emitting device or quantum dot light-emitting device.

The integrated sensor used as a semiconductor device is a technology integrating various sensors, and may include any one of touch sensors, fingerprint sensors, image sensors, pressure sensors, proximity sensors, temperature sensors, and optical sensors. Additionally, the integrated sensor may include a sensor integrated into a display, such as an active organic light-emitting device or active organic quantum dot light-emitting device, and the sensors that may be integrated may include any one of touch sensors, fingerprint sensors, image sensors, pressure sensors, proximity sensors, temperature sensors and optical sensors. Preferably, the integrated sensor may include a touch sensor integrated into an active organic light-emitting device or active organic quantum dot light-emitting device. The configuration of the touch sensor may include a surface where the touch sensors respond to direct contact (e.g., touch) or close proximity to the surface or portion thereof.

Additionally, the touch sensor may utilize touch-activated sensing technologies that can use resistive, optical, surface resilient, or capacitive techniques, or any combination thereof, but is not limited thereto.

Meanwhile, one or more semiconductor devices may be arranged to form a semiconductor device array pattern. The semiconductor device array pattern may have a width of 500 μm to 5 mm. For example, the electronic device may include various semiconductor devices and circuits according to its use, such as an active organic light-emitting device (AMOLED) or a sensor array. In particular, the shapes, sizes, or patterns may be diversified, and accordingly, the semiconductor device array patterns having different widths may be included, thereby expanding application thereof.

As the substrate, a silicon substrate, a glass substrate, or a metal substrate may be used. As the metal substrate, a metal substrate containing a high content of pure iron is inexpensive and may be easily subjected to etching, and thus, a metal containing a high content of pure iron may be preferred. Additionally, the semiconductor device may be disposed on a flexible substrate.

Zinc-indium-tin oxide (ZITO) may be applied to a flexible substrate by deposition or solution process. The ZITO-containing oxide semiconductor layer according to the present invention may be formed by coating using a solution process such as spin-coating, slit die coating, ink-jet printing, spray coating, dip coating, etc. Spin coating is a coating method by which a predetermined amount of solution is applied onto a substrate, and then the substrate is rotated at a high speed, thereby coating the substrate with a centrifugal force applied to the solution.

The flexible substrate is a substrate for supporting oxide semiconductor thin film transistors, and as the flexible substrate, a substrate having flexibility may be used. The flexible substrate may be bent or folded in a specific direction, for example, the flexible substrate may be folded in the horizontal direction, the vertical direction, or the diagonal direction.

The flexible substrate may include any one of polyimide-based polymers, polyester-based polymers, silicon-based polymers, acryl-based polymers, polyolefin-based polymers, or copolymers thereof. The flexible substrate may include at least one of polyester, polyvinyl, polycarbonate, polyethylene, polyacetate, polyimide, polyethersulphone (PES), polyacrylate (PAR), polyethylene naphthalate (PEN), and polyethylene terephthalate (PET).

Meanwhile, stretchable electronics is expected to be a technology that enables new applications of electronic devices. Potential applications include electronic skins and skin sensors for moving robotic devices, wearable electronic equipment, mobile communication devices, bio-integrated devices, rollable devices, deformable devices, automotive displays, biomedical devices and e-skin, etc. Additionally, the stretchable electronics may be usefully utilized in various fields including a display or a sensor array.

Typical stretchable electronics is a stretchable display equipment to which flexibility is added by forming a display unit on a stretchable substrate, and has a very useful advantage that it can be used by twisting or stretching its shape when necessary.

Since zinc-indium-tin oxide (ZITO) can be applied to a flexible substrate by deposition or solution process, it enables the next-generation display applicable to outer space, nuclear power plants, medical and security industries.

Meanwhile, an example of the method of preparing a radiation-durable oxide semiconductor thin film transistor for radiation exposure in which a channel layer is formed of the radiation-resistant metal oxide semiconductor composition containing radiation-resistant ZITO of the present invention described above in order to reduce performance degradation or malfunction upon exposure to radiation is as follows.

The gate electrode may be formed by depositing a gate conductive film on a substrate, forming a photoresist pattern on the gate conductive film, and then selectively etching (patterning) the gate conductive film using the photoresist pattern as a mask. The gate electrode may include a metal or metal oxide which is an electrically conductive material.

A gate insulating film may be formed on the gate electrode, and the ZITO-containing radiation-resistant oxide semiconductor layer may be formed on the gate insulating film to correspond to the gate electrode. The gate insulating film serves to insulate the gate electrode and the oxide semiconductor layer.

The radiation-durable oxide semiconductor thin film transistor (TFT) for radiation exposure according to the present invention is characterized in that a semiconductor channel layer is formed using the radiation-resistant metal oxide semiconductor composition containing ZITO of the present invention described above in order to reduce performance degradation or malfunction upon exposure to radiation.

Therefore, the ZITO-containing radiation-resistance oxide semiconductor layer may be formed by forming an oxide semiconductor film for forming an oxide semiconductor layer, and forming a photoresist pattern, followed by patterning the ZITO-containing radiation-resistance oxide semiconductor layer to correspond to the gate electrode using the photoresist as a mask.

The oxide semiconductor film for forming an oxide semiconductor layer may be formed through a chemical vapor deposition (CVD) or physical vapor deposition (PVD), or by a solution process. For example, the most common deposition method is the sputtering method, and other methods include pulsed laser deposition (PLD), atomic layer deposition (ALD), metal organic chemical vapor deposition (MOCVD), a solution process for forming a thin film by spin-coating a solution-type precursor, followed by heat treatment, and mist CVD method for forming a thin film by spraying a solution-type precursor in the form of mist, etc.

The oxide semiconductor layer may be formed into an amorphous or polycrystal including the ZITO-containing radiation-resistant material.

The oxide semiconductor layer may include a channel region in which a channel is formed and a source/drain region connected to the source/drain electrode, respectively.

The source electrode and the drain electrode may be formed on one side of the oxide semiconductor layer. The source electrode and the drain electrode may be formed at a distance from each other on the oxide semiconductor layer, and may be electrically connected to the oxide semiconductor layer, respectively. The gate electrode may be formed at distance of 0.1 μm to 3 μm in the vertical direction from the source electrode and the drain electrode formed on the ZITO-containing radiation-resistant oxide semiconductor layer.

The source electrode and the drain electrode may be formed by depositing a conductive film (hereinafter, referred to as a source/drain conductive film) for forming a source electrode and a drain electrode on the gate insulating film including the radiation-resistant oxide semiconductor layer, and forming a photoresist pattern on the source/drain conductive film, followed by patterning the source/drain conductive film using the photoresist pattern as a mask.

A passivation layer may be formed on the source electrode and the drain electrode. The passivation layer may be formed to cover all of the gate insulating layer, the oxide semiconductor layer, the source electrode, and the drain electrode. The passivation layer may be used as a protective layer and may be formed of the same material as the gate insulating layer.

Additionally, an organic semiconductor (OSC) overlayer may be applied on the channel layer. Thus, it is possible to significantly stabilize amorphous oxide semiconductor (AOS)-based TFTs against proton irradiation by effectively passivating back-channel defects by applying an organic semiconductor (OSC) overlayer. Therefore, the radiation-durable electronic device for radiation exposure according to the present invention may be equipped with a stable amorphous oxide semiconductor TFT having an OSC layer so as to mitigate damage caused by proton irradiation on the oxide semiconductor.

### Advantageous Effect

The present invention can provide a radiation-resistant oxide semiconductor composition, which can be used without malfunction in outer space or nuclear power plants exposed to a large amount of radiation such as protons, neutrons, gamma rays, etc.: a radiation-resistant thin film transistor (TFT), in which a semiconductor channel layer is formed of the radiation-resistant oxide semiconductor composition; and a radiation-durable electronic device driven by the TFT.

In the present invention, the radiation-resistant metal oxide semiconductor composition containing ZITO exhibiting radiation resistance is used in an electronic device for radiation exposure, which is used in outer space, nuclear power plants, or spaces where medical or security devices are utilized by means of radiation, and thus, the damage caused by radiation can be prevented, thereby improving the electrical properties of the device (e.g., turn-on voltage (Vₒₙ)), and the lifespan and reliability thereof.

### BRIEF DESCRIPTION OF DRAWINGS

FIG. 1 shows a schematic diagram showing TFT using a ZITO semiconductor material as a channel layer, and proton irradiation to the device.

FIG. 2 shows the change in the properties of a) ZITO (8:1:1), (b) ZITO (6:1:1), (c) ZITO (4:1:1), and (d) ZITO (2:1:1) devices and the Vg-Id change in the ZITO semiconductor thin films according to the proton radiation dose before and after 5 MeV proton irradiation with radiation doses of 10¹³ and 10¹⁴ cm⁻².

FIG. 3 shows the Vg-Id change in GSZO (1:3:6, 1:2:7), GTO (4:6), and GITO (2:1:1), which are oxide-based TFTs used as a control, according to the proton radiation dose before and after 5 MeV proton irradiation with radiation doses of 10¹³ and 10¹⁴ cm⁻².

FIG. 4 shows the change in the properties of ZITO (2:1:1) device and the Vg-Id change in the ZITO semiconductor thin film according to gamma ray and X-ray irradiation.

### DETAILED DESCRIPTION OF PREFERRED EMBODIMENTS

Hereinafter, the present invention will be described in more detail by way of Examples. However, these Examples are given for illustrative purposes only, and the scope of the invention is not intended to be limited to or by these Examples.

### Preparation Example 1

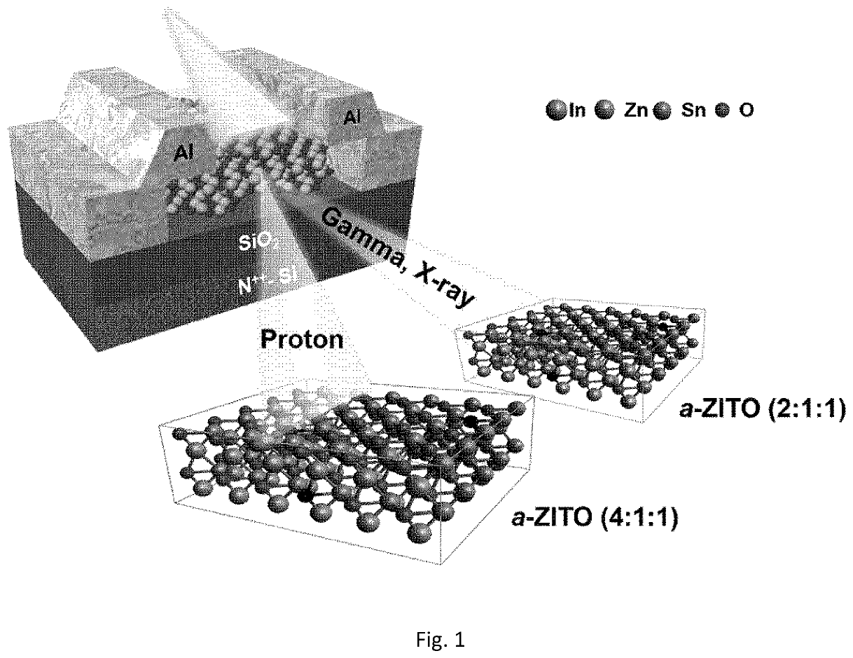

As shown in FIG. 1, TFTs using ZITO (8:1:1, 6:1:1, 4:1:1, 2:1:1)-based channel layers were fabricated through a solution process using a spin coating technique, which enables a large-scale coating with low cost, while using a heavily N-doped silicon wafer (n⁺⁺-Si) as the gate voltage, and a thermally grown-300 nm SiO₂ layer as the gate insulator.

In particular, the process of forming the ZITO-based channel layer is as follows:

After dissolving zinc acetate dihydrate, indium chloride, and tin chloride pentahydrate in 2-methoxyethanol to control the ZITO composition ratio, a spin coating precursor solution was prepared by adding ethanolamine as a stabilizer. In particular, the total molar concentration of the metals was 0.075 M. After subjecting the solution to spin coating, a thin film was formed by annealing at high temperature of about 400° C., which was then used as a channel layer.

### Example 1: Changes in Properties of ZITO Devices According to Proton Irradiation

After irradiating 5 MeV protons to the TFT devices equipped with ZITO channel layers having various composition ratios fabricated in Preparation Example 1 with radiation doses of 10¹³ and 10¹⁴ cm⁻², the change in the properties of the TFT devices according to the proton irradiation was confirmed.

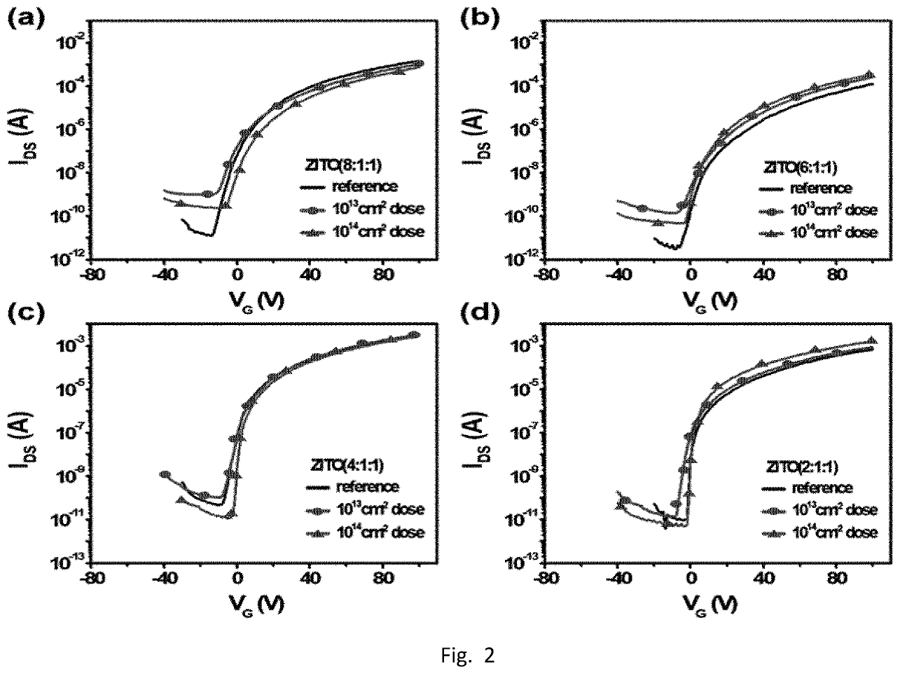

As shown in FIG. 2, ZITO-based thin film transistors showed superior stability against protons at all composition ratios of ZITO compared to other previously reported oxides (IGZO, ZnO, ZTO). In particular, ZITO (4:1:1) showed the highest stability among them. The on voltage (Vₒₙ), threshold voltage (Vₜₕ), and mobility (μ), which are parameters for evaluating the performance of transistors, were nearly changed until the radiation dose of 10¹⁴ cm⁻².

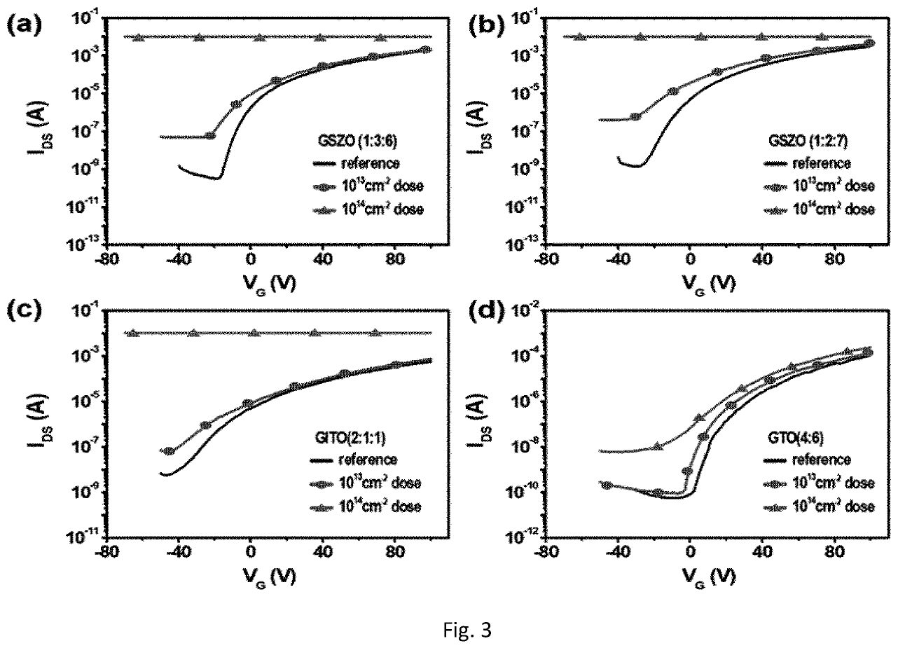

Meanwhile, as shown in FIG. 3, GSZO (1:3:6, 1:2:7), GTO (4:6), and GITO (2:1:1)-based thin film transistors used as a control exhibited proton resistance significantly lower than ZITO (4:1:1). When the on voltage (Vₒₙ), threshold voltage (Vₜₕ) and mobility (μ), which are parameters for evaluating the performance of transistors were measured, it was confirmed that the on voltage (Vₒₙ) and the threshold voltage (Vₜₕ) of GSZO (1:3:6, 1:2:7) and GITO (2:1:1) increased in the negative direction from the radiation dose of 10¹³ cm⁻² and became fully conducted at the radiation dose of 10¹⁴ cm⁻². It seemed that GTO (4:6) was slightly more stable than GSZO and GITO, but the on voltage (Vₒₙ) was shifted by about 40 V in the negative direction at the radiation of dose of 10¹⁴ cm⁻², confirming that the radiation resistance was remarkably reduced compared to ZITO (4:1:1).

### Example 2: Changes in Properties of ZITO Devices According to Gamma Irradiation

The electrical stability of the devices was confirmed by irradiating 1 MeV gamma rays with radiation dose of 10M rad (100 Kgy) and 10 MeV X-rays with radiation dose of 10 Kgy to the TFT devices equipped with ZITO channel layers having various composition ratios fabricated in Preparation Example 1.

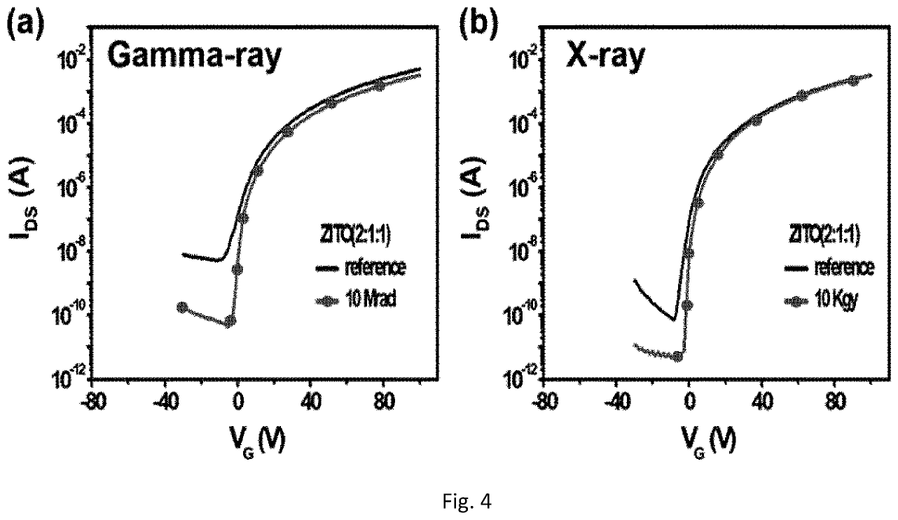

As shown in FIG. 4, in particular, the ZITO (2:1:1)-based thin film transistor showed excellent stability against gamma and X-rays. When the gamma rays were irradiated to the level of 10 Mrad, there was a slight decrease in mobility from 9 cm²/Vs to 6.6 cm²/Vs, and the on voltage and threshold voltage were shifted by about 4 V. Additionally, when the x-rays were irradiated to the level of 10 Kgy, it was confirmed that there was almost no change in the mobility and the threshold voltage.

1. A radiation-resistant metal oxide semiconductor composition containing zinc-indium-tin oxide (ZITO) exhibiting radiation resistance.

2. The radiation-resistant metal oxide semiconductor composition of claim 1, wherein the ZITO is resistant to proton rays, gamma rays, and X-rays.

3. The radiation-resistant metal oxide semiconductor composition of claim 1, wherein the composition of ZITO for exhibiting radiation resistance is controlled within the range of Zn:In:Sn=4 to 2:1:1.

4. The radiation-resistant metal oxide semiconductor composition of claim 1, wherein the ZITO exhibiting radiation resistance forms a metal oxide semiconductor layer of a radiation-resistant electronic device.

5. The radiation-resistant metal oxide semiconductor composition of claim 1, wherein the ZITO exhibiting radiation resistance forms a metal oxide semiconductor layer of a radiation-resistant transistor.

6. The radiation-resistant metal oxide semiconductor composition of claim 1, wherein the composition is a radiation-resistant oxide semiconductor target formed by sintering ZITO.

7. A radiation-durable oxide thin film transistor (TFT) for radiation exposure, wherein a channel layer is formed of the radiation-resistant metal oxide semiconductor composition containing radiation-resistant ZITO of claim 1 in order to reduce performance degradation or malfunction when exposed to radiation.

8. A radiation-durable electronic device for radiation exposure, wherein a radiation-resistant metal oxide semiconductor layer is formed of the radiation-resistant metal oxide semiconductor composition containing radiation-resistant ZITO of claim 1 in order to reduce performance degradation or malfunction when exposed to radiation.

9. The radiation-durable electronic device for radiation exposure of claim 8, wherein the electronic device is used in outer space, nuclear power plants, or in spaces where medical or security devices are utilized by means of radiation.

10. The radiation-durable electronic device for radiation exposure of claim 8, wherein the electronic device is equipped with a radiation-durable transistor, in which a channel layer is formed of the radiation-resistant metal oxide semiconductor composition containing radiation-resistant ZITO of claim 1.

11. A method for preparing the radiation-resistant metal oxide semiconductor composition containing radiation-resistant ZITO of claim 1, comprising confirming the formation of oxygen vacancy or the degree thereof in a metal oxide semiconductor material or metal oxide semiconductor layer by irradiating protons to a ZITO-containing metal oxide semiconductor material having a specific composition ratio of Zn:In:Sn or a device fabricated using the same.

12. The method of claim 11, wherein the formation of oxygen vacancy or the degree thereof is confirmed by determining the amount of free electrons generated when oxygen vacancy exists in the metal oxide semiconductor material or metal oxide semiconductor layer to be analyzed.

13. The method of claim 11, wherein the formation of oxygen vacancy or the degree thereof is determined by analyzing electron spin resonance (ESR) peaks obtained from free electrons generated at the oxygen vacancy in the metal oxide semiconductor material through ESR before and after proton irradiation, and/or analyzing O vacancy peaks and/or M-OH peaks through X-ray photoelectron spectroscopy (XPS).

14. The method of claim 11, further comprising confirming the degree of turn-on voltage (Vₒₙ) change before or after irradiation of proton rays, gamma rays, or X-rays after fabricating an oxide semiconductor TFT device, in which the ZITO-containing metal oxide semiconductor material to be analyzed is used as a channel layer.

15. The method of claim 11, further comprising determining the crystal structure and/or the contents of zinc (Zn), indium (In), and tin (Sn) of the ZITO-containing oxide semiconductor material to order to impart a desired degree of radiation resistance to the ZITO-containing oxide semiconductor material.

16. A method for evaluating the radiation durability of an electronic device fabricated using a ZITO-containing metal oxide semiconductor material, comprising confirming the formation of oxygen vacancy or the degree thereof in a metal oxide semiconductor layer by irradiating protons to an electronic device fabricated using a ZITO-containing metal oxide semiconductor material.

17. The method of claim 16, wherein the formation of oxygen vacancy or the degree thereof is confirmed by determining the amount of free electrons generated when oxygen vacancy exists in the metal oxide semiconductor material or metal oxide semiconductor layer to be analyzed.

18. The method of claim 16, wherein the formation of oxygen vacancy or the degree thereof is determined by analyzing ESR peaks obtained from free electrons generated at the oxygen vacancy in the metal oxide semiconductor material through electron spin resonance (ESR) before and after proton irradiation, or analyzing O vacancy peaks and/or M-OH peaks through X-ray photoelectron spectroscopy (XPS).

19. The method of claim 16, further comprising confirming the degree of turn-on voltage (Vₒₙ) change before or after irradiation of proton rays, gamma rays, or X-rays after fabricating an oxide semiconductor TFT device, in which the ZITO-containing metal oxide semiconductor material to be analyzed is used as a channel layer.
